(19) United States
(12) Patent Application Publication
(10) Pub. No.: US 2017/0047487 A1
(43) Pub. Date: Feb. 16, 2017

(54) OPTOELECTRONIC MODULES HAVING FEATURES FOR REDUCING THE VISUAL IMPACT OF INTERIOR COMPONENTS

(71) Applicant: Heptagon Micro Optics Pte. Ltd., Singapore (SG)

(72) Inventors: Markus Rossi, Jona (CH); Jens Geiger, Thalwil (CH); Jonathan Hobbis, Zurich (CH); René Kromhof, Wollerau (CH); Olivier Ripoll, Rüschlikon (CH)

(21) Appl. No.: 15/304,269

(22) PCT Filed: Apr. 14, 2015
(86) PCT No.: PCT/SG2015/050070

§ 371 Date: Oct. 14, 2016

Related U.S. Application Data
(60) Provisional application No. 61/980,778, filed on Apr. 17, 2014.
(60) Provisional application No. 62/008,878, filed on Jun. 6, 2014.

(51) Int. Cl. H01L 33/50; F21V 9/16; F21V 9/08; F21V 23/06; G02B 5/23; G03B 15/06; H01L 33/48; H01L 33/58; H01L 33/60; F21V 3/04; F21V 7/22

(52) U.S. Cl. CPC H01L 33/502; F21V 3/04; F21V 9/16; F21V 9/08; F21V 23/06; F21V 7/22; G03B 15/06; H01L 33/486; H01L 33/507; H01L 33/58; H01L 33/60; G02B 5/23; F21Y 2115/10

(57) ABSTRACT

Light emitting modules, such as flash modules, include features to help reduce the visual impact of interior components and shield them from view. The features also may enhance the outer appearance of the module or of an appliance incorporating the module.

### FIELD OF THE DISCLOSURE

The present disclosure relates to optoelectronic modules having features for reducing the visual impact of interior components.

### BACKGROUND

Many electronic appliances, including consumer products, industrial appliances and medical devices, have a light emitting element for emitting optical signals outside the device and/or a light receiving element for sensing light received from outside the device. Depending on the particular application, the wavelength of the light to be emitted or detected may be in the ultra-violet (UV), infra-red (IR) or visible range. For some applications, particularly those that rely on light in the visible range (e.g., about 390 nm to about 750 nm), a small opening (e.g., a hole or slit) or window may be provided in the housing (e.g., a casing) of the device so that the light can be emitted to an external location or so that light can be received from an external location. In some cases, one or more windows are provided in the housing so that optical signals in the visible range can be emitted as well as received by optoelectronic components inside the appliance. For example, some mobile phones include a window in their housing so that optical signals can be received by a camera integrated within the phone. A second window adjacent the first window may be provided so that light from a flash inside the phone can be emitted when a photograph is to be taken using the camera.

Although such openings or windows in the housing of the appliance may be important to facilitate various functions, the windows may detract from the overall appearance of the appliance. For example, the presence of windows or other openings in the housing may make some of the internal components visible to someone looking at the appliance when it is in an unilluminated state. This may be undesirable in some cases either for functional or aesthetic reasons.

### SUMMARY

The present disclosure describes various optoelectronic modules that include features to help reduce the visual impact of interior components and shield them from view. Some of the features also may enhance the outer appearance of the module or of an appliance incorporating the module.

According to one aspect, a flash module includes a light emitting element mounted on a substrate. The light emitting element has a light emitting surface at least partially covered by a wavelength conversion material. A cover, which is substantially parallel to the substrate, is disposed over the light emitting element and the wavelength conversion material. The cover is composed of a material that is substantially transparent to light to be emitted from the module. A spacer separates the cover from the substrate and laterally encircles the light emitting element. A layer on the cover is composed of a material that is substantially non-transparent to light in the visible part of the spectrum. The layer has through-holes that allow light from the light emitting element to pass out of the module, but that are sufficiently small (e.g., ≦0.1 mm diameter or side) so as to reduce the visual impact of the layer.

Some implementations include one or more of the following features. For example, in some cases, the through-holes have a diameter in the range of 0.05 mm-0.1 mm. In some instances, the through-holes may be smaller than is resolvable by an unaided human eye. In some implementations, dimensions and/or a pattern of the through-holes simulate a textured appearance of an exterior housing of a device (e.g., a smartphone) in which the light emitting module is disposed. The layer on the cover may have a thickness, for example, of less than 10 μm and may be composed, for example, of black chrome.

According to another aspect, a light emitting module includes a light emitting element mounted on a substrate. The light emitting element has a light emitting surface at least partially covered by a wavelength conversion material. A cover, which is substantially parallel to the substrate, is disposed over the light emitting element and the wavelength conversion material, and is composed of a material that is substantially transparent to light to be emitted from the module. A spacer separates the cover from the substrate. A visual impact reduction member is disposed on the cover at a location that intersects an optical emission axis of the light emitting element. The visual impact reduction member is composed of a material that reduces a visual impact of the light emitting element and wavelength conversion material when viewed from outside the module while the light emitting element is not emitting light. An optics part laterally surrounds the light emitting element includes a reflective surface. The optics part is arranged so that light exiting the wavelength conversion material is reflected by the visual impact reduction member toward the reflective surface of the optics part, which redirects the light out of the module through the transparent cover. In some cases, the reflective surface of the optics part comprises a low-emissivity, highly reflective coating.

In accordance with yet a further aspect, a light emitting module includes a light emitting element mounted on a substrate and arranged to emit light in a direction generally parallel to the substrate. A wavelength conversion material is positioned within a path of light from the light emitting element. An optics part adjacent the substrate includes a reflective surface that intersects an optical emission axis of the light emitting element. A cover, which is substantially parallel to the substrate, is disposed over the light emitting element, the wavelength conversion material and the optics part, and is composed of a material that is substantially transparent to light to be emitted from the module. A spacer separates the cover from the substrate. A substantially opaque layer on a portion of the cover extends over the light emitting element and the wavelength conversion material so as to reduce a visual impact of the light emitting element and wavelength conversion material when viewed from outside the module while the light emitting element is not emitting light. The module is arranged so that light exiting the phosphor material is reflected by the reflective surface of the optics part, which redirects the light out of the module through a portion of the transparent cover on which the spacer is not disposed.

According to another aspect, a light emitting module includes a light emitting element mounted on a substrate. A wavelength conversion material is disposed in an area of the module spaced apart from the light emitting element. A cover substantially parallel to the substrate has a first section disposed over the wavelength conversion material and is composed of a material that is substantially transparent to light to be emitted from the module. A substantially opaque layer extends over the light emitting element so as to reduce a visual impact of the light emitting element from outside the module while the light emitting element is not emitting light. A height of the wavelength conversion material in a direction from the substrate toward the cover is sufficiently small so as to reduce a visual impact of the phosphor when viewed from outside the module while the light emitting element is not emitting light. The module is arranged so that at least some light emitting element light that enters the wavelength conversion material is converted to light of a different wavelength which subsequently exits the module through the first section of the cover.

Another aspect describes a light emitting module that includes a light emitting element mounted on a substrate. A cover, which is substantially parallel to the substrate, is disposed over the light emitting element and is composed of a material that is substantially transparent to light to be emitted from the module. A spacer separates the cover from the substrate and laterally encircles the light emitting element. A layer on the cover has a substantially transparent state and a substantially opaque state, wherein the layer changes from the opaque state to the transparent state in response to at least one of a change in light, a change in temperature, or a change in voltage or current applied to the layer. For example, if the layer is a photochromic layer that changes from the opaque state to the transparent state in response to light generated by the light emitting element. In some implementations, a color of the photochromic layer in the opaque state substantially matches a color of a housing of a device in which the module is disposed. When the light emitting element emits light, the photochromic layer can become transparent so that light is emitted from the module. The photochromic layer can remain in the transparent state while the light emitting element emits light, and then can transition back to the opaque state after the light emitting element is turned off.

Other aspects, features and advantages will be readily apparent from the following detailed description, the accompanying drawings and the claims.

### BRIEF DESCRIPTION OF THE DRAWINGS

FIG. 1 illustrates an example of a smartphone.

FIG. 2 illustrates an example of a light emitting module.

FIGS. 3A-3D illustrate an example of a wafer-level method of fabricating flash modules as in FIG. 2.

FIG. 4A illustrates another example of a light emitting module.

FIG. 4B illustrates yet another example of a light emitting module.

FIG. 5A illustrates a further example of a light emitting module.

FIG. 5B illustrates another example of a light emitting module.

FIG. 6A illustrates yet another example of a light emitting module.

FIG. 6B illustrates a further example of a light emitting module.

FIG. 6C illustrates another example of a light emitting module.

FIG. 6D illustrates yet another example of a light emitting module.

FIG. 7 illustrates another example of a light emitting module.

### DETAILED DESCRIPTION

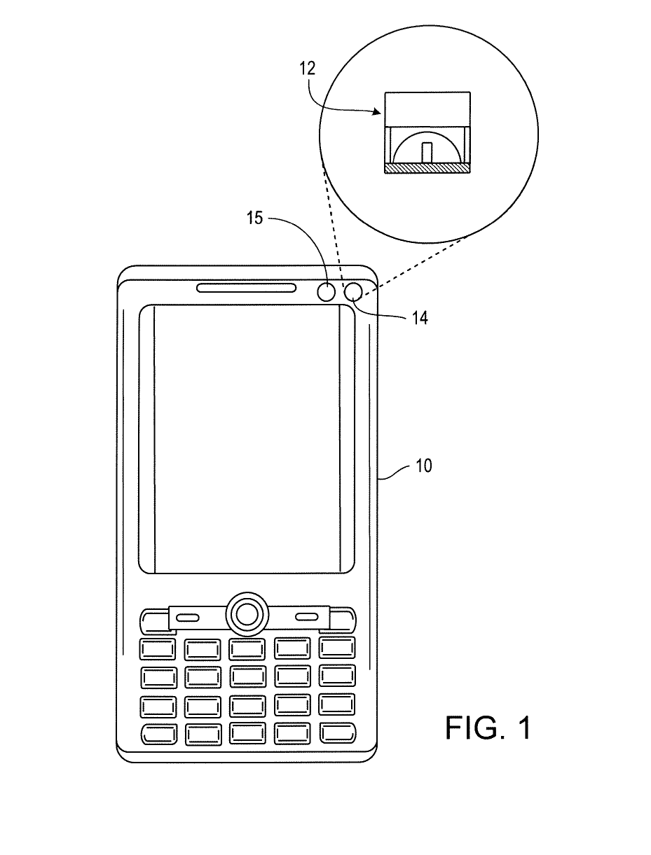

As shown in FIG. 1, a smartphone 10, which is an example of portable computing device, includes a light emitting module 12 within its housing. The module 12 may be used, for example, as a flash module in conjunction with an image capturing device such as a camera that also is integrated within the smartphone 10 and can be interconnected to other components of the device, which may include, for example, a processor, memory, an input/output device such as a display, a communication interface, and a transceiver, and other components. In some cases, the module 12 can be used to alert a user to incoming calls, messages, or other alerts. The various components on the smartphone or other device 10 can be interconnected using various buses, and several of the components may be mounted on a common motherboard or in other manners as appropriate. In some implementations, the module 12 is mounted on the common motherboard with some of the other components.

Some or all of the outer surfaces of smartphone or other device 10 may be composed of light blocking material. This may be done, in some implementations, either for aesthetic or functional reasons (e.g., to reduce the amount of stray light entering the housing). For example, at least some of the outer surfaces may be composed of a black material that absorbs a significant amount of, and preferably substantially all, the light in the visible spectrum that impinges on those surfaces of the smartphone or other device.

A surface of the smartphone 10 includes a window 14 that permits light emitted by the module 12 to exit the housing of the smartphone 10. The module 12 can be located directly below the window 14. A camera may be positioned directly below a second window 15 that is adjacent the first window 14. If the windows are composed, for example, of a transparent glass or plastic material, then the module 12 may be visible from the outside. In various applications, however, it may be desirable to design the module 12 such that the module 12 is not readily visible when viewed from outside the housing (e.g., when looking at window 14). The following paragraphs describe examples of light emitting modules that include features that can reduce the visual impact of the module even when it is an unilluminated state.

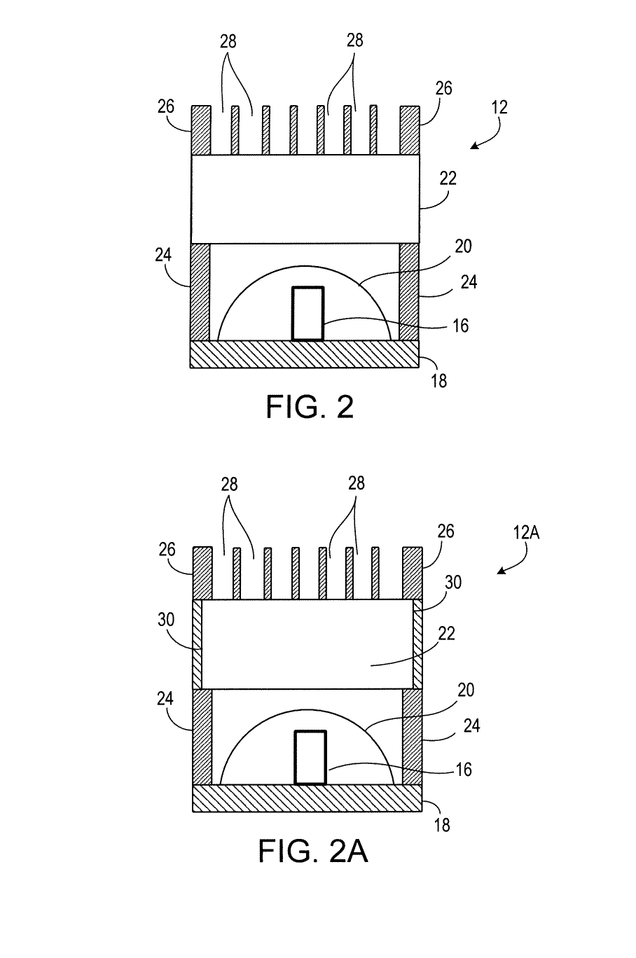

An example of module 12 is illustrated in FIG. 2 and includes a light emitting component such as a vertical light emitting diode (LED) 16. The LED 16 is mounted on a substrate (i.e., a support) 18, which may be composed, for example, of a printed circuit board (PCB) material. The light emitting surface of the LED 16 can be at least partially covered by a phosphor material 20 to convert the wavelength of light emitted by the LED 16, for example, from blue light to white light. A cover 22, which may be composed, for example, of glass or polymer, is disposed over the LED 16 and the phosphor 20 and can be substantially parallel to the substrate 18. The cover 22, which is substantially transparent to the wavelength(s) of light to be emitted from the module, is separated from the substrate 18 by a spacer 24 that laterally encircles the LED 16. The spacer 24 can serve as sidewalls of the module.

The spacer 24 can ensure a well-defined distance between substrate 18 and transparent cover 22 (through its vertical extension). In some implementations, the spacer 24 is composed of a polymer material, for example, a hardenable (e.g., curable) polymer material, such as an epoxy resin that is substantially opaque.

Electrical contacts for the LED 16 can be connected electrically to outside the module 12 (e.g., the exterior of the substrate 18), where conductive pads are attached. The module 12 thus can be mounted on a printed circuit board, e.g., using surface mount technology (SMT), next to other electronic components. The printed circuit board may be a constituent of the smartphone or other device 10.

As shown in FIG. 2, to reduce the visual impact of the module's internal components (e.g., the LED 16 and phosphor 20) so that they are less visible (or are invisible) to a person looking at the module 12 through the window 14 on the surface of the smartphone or other device 10, a thin layer 26 (e.g., ≦10 μm), for example, of black chrome, can be provided on the transparent cover 22. In some cases, the thin layer 26 can be composed of a photolithographic material. The thin layer 26 should be composed of a material that is substantially non-transparent to light in the visible part of the spectrum. The thin layer 26 has very small through-holes 28 that extend entirely through the thickness of the layer 26. The through-holes 28, which can take the form, for example, of slits or circular openings, allow light from the LED 16 to pass out of the module 12, but can be sufficiently small (e.g., ≦0.1 mm diameter (if circular) or ≦0.1 mm side (if square)) so as to reduce the visual impact of the phosphor. In some cases, the through-holes 28 have a diameter or side that falls within one of the following ranges: 0.05 mm-0.1 mm; 0.05 mm-0.09 mm; 0.05 mm-0.08 mm; 0.05 mm-0.07 mm; 0.05 mm-0.06 mm; 0.04 mm-0.05 mm; 0.03 mm-0.05 mm; or 0.02 mm-0.05 mm. In some cases, the dimensions and/or pattern of the through-holes 28 can match or simulate the textured appearance of the exterior housing of the smartphone or other device. Also, in some instances, the through-holes 28 are smaller than is resolvable by the unaided human eye (e.g., about 0.1 mm at a distance of 1 meter). In this way, if the module 12 is integrated into a smartphone or other device 10, the presence of the module 12 inside the smartphone 10 or other device is not easily detected by the naked human eye when the module is in an unilluminated state.

In some implementations, as illustrated in FIG. 2A, it is desirable to encapsulate the transparent cover 22 of the module 12A with an opaque material 30. In this way, sidewalls of the transparent cover 22 are covered by a material that is non-transparent to light emitted by the module. In some cases, the opaque material 30 has the same composition as the spacer 24, for example, a hardenable (i.e., curable) polymer material, such as a black epoxy resin.

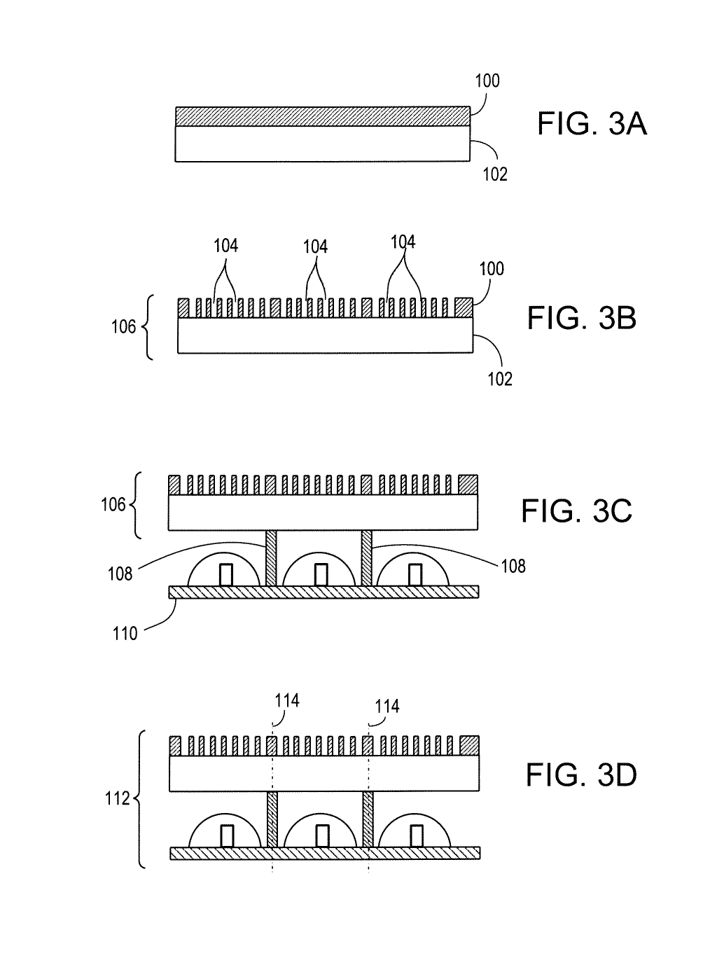

FIGS. 3A through 3D illustrate an example process for fabricating a module as in FIG. 2. In some implementations, a wafer-level process can be used to make multiple modules in parallel (i.e., at the same time). Generally, a wafer refers to a substantially disk- or plate-like shaped item, its extension in one direction (y-direction or vertical direction) is small with respect to its extension in the other two directions (x- and z- or lateral directions). In some implementations, the diameter of the wafer is between 5 cm and 40 cm, and can be, for example, between 10 cm and 31 cm. The wafer may be cylindrical with a diameter, for example, of 2, 4, 6, 8, or 12 inches, one inch being about 2.54 cm. In some implementations of a wafer level process, there can be provisions for at least ten modules in each lateral direction, and in some cases at least thirty or even fifty or more modules in each lateral direction.

As shown in the example of FIG. 3A, a thin, non-transparent layer (e.g., black chrome) 100 is deposited on a surface of a transparent wafer 102. The wafer 102 may be composed, for example, of glass or a polymer material. Through-holes 104 are formed in the non-transparent layer 100, thereby forming a sub-assembly 106 of the non-transparent layer 100 (having through-holes 104) and the transparent wafer 102 (see FIG. 3B). The dimensions, shape, spacing and pattern of the through-holes 104 can be chosen to be consistent with the features of the module described above (i.e., such that light from a flash LED can pass through the transparent wafer 102 and the through-holes 104, but such that the visual impact of the assembly is reduced). The through-holes 104 can be formed in any one of several ways, such as by drilling or etching. If the through-holes 104 are formed by etching, then a mask with an appropriate pattern for the through-holes 104 can be provided.

Next, as shown in FIG. 3C, the sub-assembly 106 is attached to one side of a spacer wafer 108, the other side of which is attached to a substrate wafer 110. The spacer wafer 108 can be composed, for example, of a non-transparent material, such as a vacuum injected polymer material (e.g., epoxy, acrylate, polyurethane, or silicone) containing a non-transparent filler (e.g., carbon black, pigment, or dye). The substrate wafer 110 can be composed, for example, of a PCB material 40 such as FR4, which is a grade designation assigned to glass-reinforced epoxy laminate material. Multiple light emitting elements (e.g., LEDs) 16 are mounted on the surface of the substrate wafer 110 and are separated from one another by portions of the spacer wafer 108, which laterally encircles each LED 16. The LEDs 16 can be covered at least partially by a phosphor material 20. Electrical contacts for each LED 16 can be connected electrically to conductive pads on the other side of the substrate wafer 110. As illustrated in FIG. 3D, the resulting stack 112 can be separated (e.g., diced) vertically along dicing lines 114 into multiple modules, each of which is similar to the module of FIG. 2.

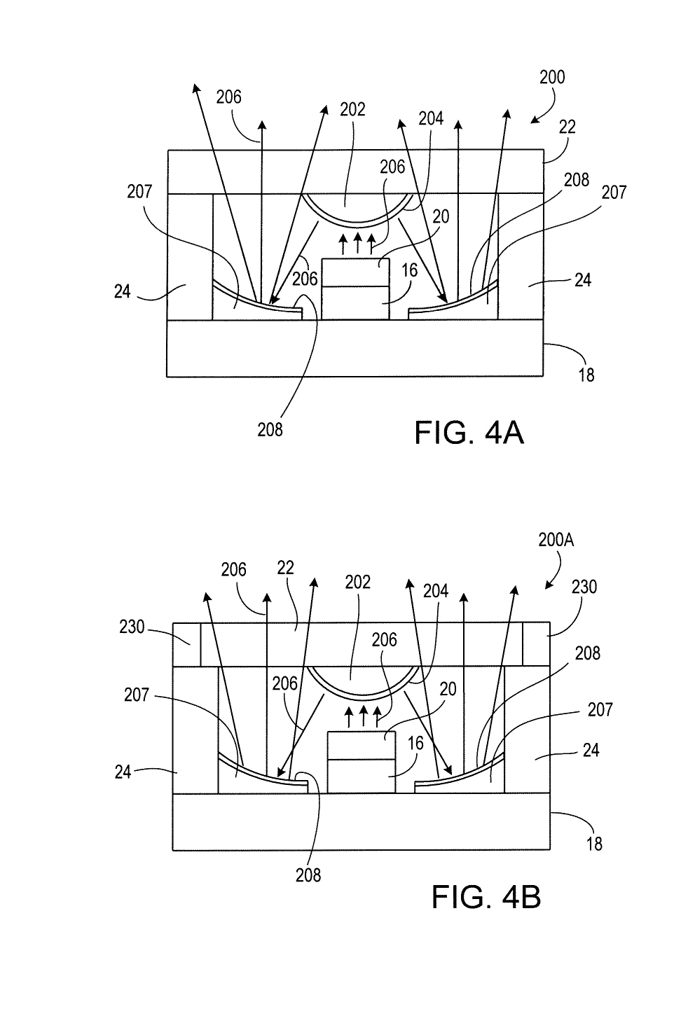

FIG. 4A illustrates another example of a light emitting module 200 that includes a light emitting element such as a vertical light emitting LED 16 mounted on a substrate. As in the previous example, the light emitting surface of the LED 16 can be covered by a phosphor material that converts the light emitted by the LED, for example, to white light. A transparent cover 22 is disposed over the LED substantially parallel to the substrate 18, and is separated from the substrate 18 by a spacer 24. Other details of the substrate 18, spacer 24 and transparent cover 22 can be substantially similar to the corresponding features of the module 12 in FIG. 2.

As further shown in FIG. 4A, the LED-side of the transparent cover 22 has a visual impact reduction member 202 that is located directly over the LED 16 and the phosphor material 20. The member 202 intersects the emission axis of the LED 16, and can be composed of a material that reduces the visual impact of the phosphor material 20 and LED 16 (i.e., when the module 200 is viewed through the window 14 of the smartphone or other device 10 along the optical emission axis of the LED 16). Examples of the material for the member 202 include injectable and curable materials such as an epoxy composite, where the epoxy composite has substantially the same color as the housing of the smartphone or other device 10. In some instances, the epoxy composite is an epoxy that includes carbon particles such that it appears black. In the illustrated example, the visual impact reduction member 202 is formed as a semi-spherical projection on the LED-side of the transparent cover 22, but may have a different shape in other implementations. In some instances, the visual impact reduction member 202 can be formed on the surface of the cover 22 by a replication technique or it may be positioned on the cover 22 by a pick-and-place technique. The lateral dimensions of the visual impact reduction member 202 should be sufficiently large that they are present directly above the lateral dimensions of the LED 16 and phosphor 20 such that the visual impact of the LED 16 or phosphor 20 material are reduced for a person looking at the cover 22 of the module 200 along the optical axis of the LED 16.

To reflect the light 206 out of the module 200, the surface of the visual impact reduction member 202 that faces the LED 16 can be coated with a low emissivity, highly reflective material 204. An optics part is provided on the same surface of the substrate 18 as the LED 16 and includes curved, minor substrates 207 that laterally surround the LED 16. The minor substrates 207 can be formed, for example, by a replication technique. The upper surfaces of the mirror substrates 207 can be covered, for example, with a low-emissivity, highly reflective coating 208 to enhance their reflectivity. Light emitted by the LED 16 passes through the phosphor 20, where it is converted, for example, to white light, which subsequently is reflected by the reflective layer 204 on the visual impact reduction member 202. Most of the light can be reflected by the reflective layer 204 toward the reflective surface 208 on the minor substrates 207, which direct the light through the transparent cover 22 and out of the module 200.

As mentioned, each of the coating layers (i.e., 204 and 208) can be composed of a low emissivity material, where a material's emissivity indicates the relative ability of the material's surface to emit energy by radiation compared to an ideal black body. The respective emissivity of each coating layer 204, 208 preferably has a value between 0 and 1. In some implementations, the maximum emissivity should be about 0.1. Examples of suitable low emissivity materials include metals such as copper (Cu), aluminum (Al), gold (Au), nickel (Ni), titanium (Ti) and tungsten (W), particularly such metals having a polished or blank surface. For example, at a temperature of about 25° C., polished Cu, Al, Au and Ni have emissivity values of about 0.05.

Electrical contacts for the LED 16 can be connected electrically to outside the module 200 (e.g., the exterior of the substrate 18), where conductive pads are attached. The light emitting module 200 thus can be mounted on a printed circuit board, e.g., using surface mount technology (SMT), next to other electronic components. The printed circuit board may be a constituent of the smartphone or other device 10.

In some implementations, as illustrated in FIG. 4B, it is desirable to encapsulate the transparent cover 22 of the module 200A with an opaque material 230. In this way, sidewalls of the transparent cover 22 are covered by a material that is non-transparent to light emitted by the module. In some cases, the opaque material 230 has the same composition as the spacer 24, for example, a hardenable (i.e., curable) polymer material, such as a black epoxy resin.

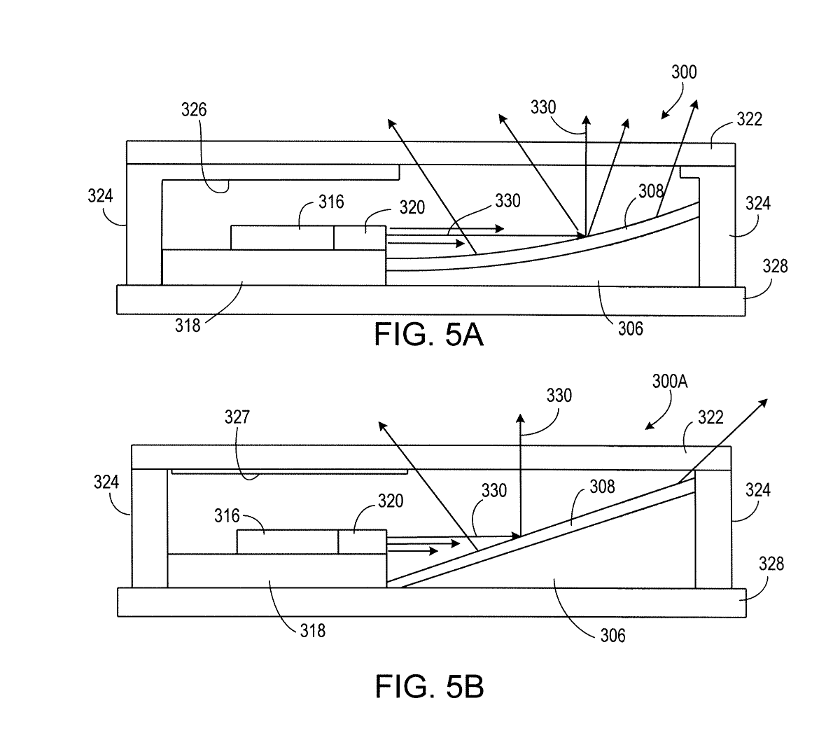

FIG. 5A illustrates an example of a module 300 that includes a light emitting element such as a laser 316 mounted on a support 318. A phosphor material 320 is positioned within a path of the laser light to convert the light emitted by the laser, for example, from blue to white light. An optics part is provided adjacent the support 318 and includes a curved, minor substrate 306 that intersects the optical emission axis of the laser 316. The surface of the minor substrate 306 can be covered, for example, with a low-emissivity, highly reflective coating 308 to enhance its reflectivity. The same low-emissivity materials described above can be used for the coating 308 as well. Light emitted by the laser 316 passes through the phosphor 320, where it is converted, for example, to white light 320, which subsequently is reflected, by the reflective coating 308, through the transparent cover 322 and out of the module 300.

The support 318 and the minor substrate 306 can be mounted on a substrate 328 that serves as the bottom of the module housing. A spacer 324 separates the substrate 328 from the transparent cover 320. The respective compositions of the substrate 328 and transparent cover 322 can be substantially similar to the corresponding features of the module 12 in FIG. 2.

As illustrated in FIG. 5A, a portion 326 of the spacer 324 extends along the light emitting element-side of the transparent cover 322 such that it is separates the laser 316 and phosphor 320 from the transparent cover 322. Thus, the laser 316 and phosphor 320 are located within the module 300 to one side of the spacer portion 326, and part of the transparent cover 322 is located on the other side of the spacer portion 326. The spacer 324 (including the portion 326) can be composed, for example, of a black material that absorbs most, if not all, light in the visible part of the spectrum so as to reduce the visual impact of the light emitting element 316 and phosphor material 320 to a person looking toward the exterior side of the cover 222. Although the transparent cover 322 also extends over the optics part 306, the spacer portion 326 does not extend over the optics part 306, thereby allowing the light 330 to exit the module.

Electrical contacts for the light emitting element 316 can be connected electrically to outside the module 300 (e.g., the exterior of the substrate 328), where conductive pads are attached. The light emitting module 300 thus can be mounted on a printed circuit board, e.g., using surface mount technology (SMT), next to other electronic components. The printed circuit board may be a constituent of the smartphone or other device 10.

Various modifications can be made to the module 300 of FIG. 5A. For example, as illustrated in the module 300A of FIG. 5B, in some implementations, the optics part 306, 308 can provide an inclined, flat surface, rather than a curved surface. Also, in some implementations, instead of extending a portion 326 of the spacer 324 over the light emitting element 316 and phosphor material 320, an opaque coating 327, such as black chrome, can be provided on a surface of the transparent cover 322 over the light emitting element 316 and phosphor material 320. In such implementations, the transparent cover 322 extends over the light emitting element 316 and phosphor material 320 as well as the optics part 306, and the opaque coating 327 can be provided either on the light emitting element-side of the cover 322 or on its exterior side. The opaque coating 327, however, does not extend over the optics part 306, thereby allowing the light 330 to exit the module. Further, in some cases, the color of the opaque coating 327 can substantially match a color of the housing of the smartphone or other device 10 in which the module 300A is disposed. In some instances, different combinations of features from the examples of FIGS. 5A and 5B may be present.

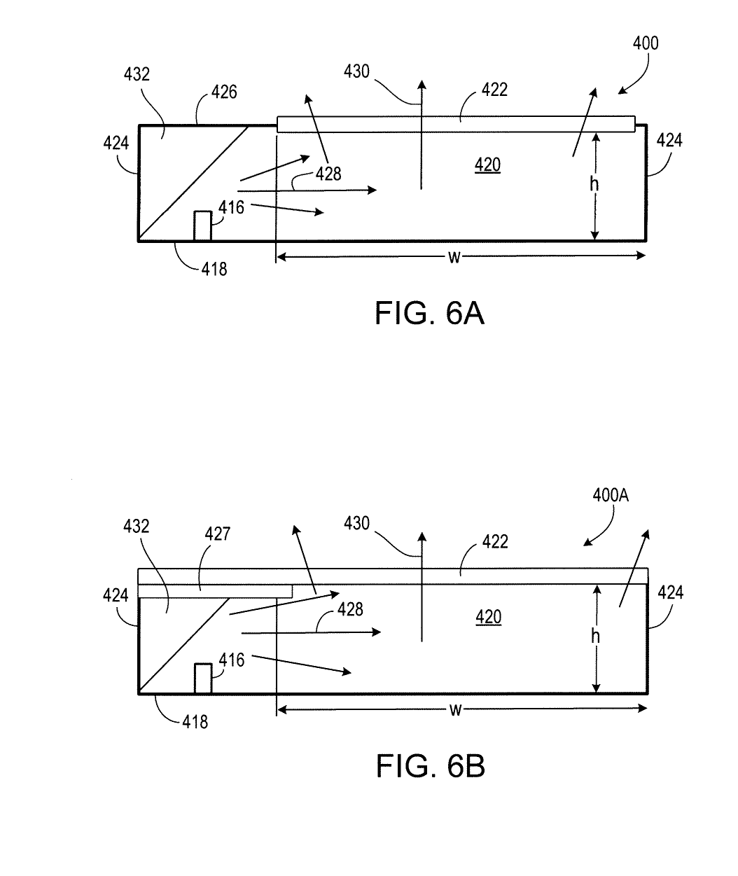

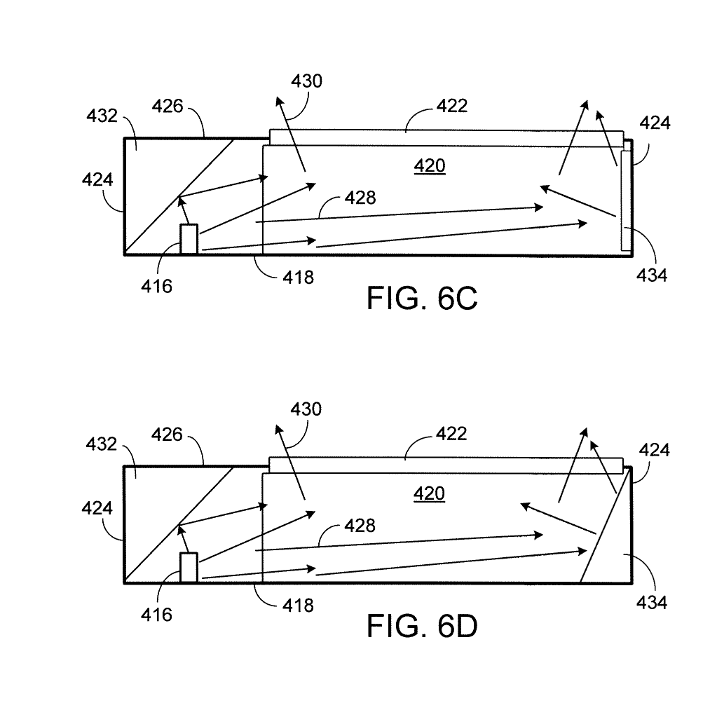

FIG. 6A illustrates an example of a module 400 that includes a light emitting element, such as a LED 416, mounted on a substrate 418. In this implementation, the phosphor material 420 that converts the LED light, for example, from blue to white light need not be disposed directly on the LED 416. Instead, the phosphor material 420 can be spaced away laterally from the LED 416 and substantially may fill an area between the substrate 418 and a transparent cover 422 disposed directly over the phosphor material 420. The phosphor material 420 can be a composite of an inorganic phosphor suspended, for example, in a silicon-based organic polymer (e.g., polydimethylsiloxane (PDMS)). The width (w) of the area containing the phosphor material 420 should be sufficiently large such that the phosphor material can perform its optical conversion function (i.e., convert the LED light from blue to white light). On the other hand, the height (h) of the phosphor material 420 can be relatively thin such that its visual impact, when viewed through the transparent cover 422, is reduced. In general, the width to height ratio (w/h) of the phosphor material needed to achieve a particular visual impact will depend, at least in part, on the concentration of phosphor suspended in the silicone. Thus, for example, if the phosphor concentration is relatively high, the w can be made smaller to meet the host device specification. On the other hand, if the phosphor concentration is relatively low, then w or h may need to be made higher to achieve the same visual impact. In some implementations, the w/h ratio of the phosphor material is in the range of 5/1 to 100/1. A w/h ratio in the range of about 10/1 to 50/1 may be appropriate in some instances.

In situations where the light emitting element 416 directs light upwardly, it also can be advantageous to provide a reflector 432 that intersects the light emitting element's optical emission axis so as to reflect the laser light 428 toward the phosphor material 420. The surface of the reflector 432 can be coated, for example, with a low-emissivity, highly reflective coating to enhance its reflectivity. The same low-emissivity materials described above can be used for the coating here as well. In operation, light 428 emitted by the light emitting element 416 passes through the phosphor 420, where it is converted, for example, to white light 420, at least some of which subsequently passes through the transparent cover 422 and out of the module 400.

To help reduce the visual impact of the light emitting element 416, a non-transparent cover 426 can be disposed over the light emitting element 416 as well as over the reflector 432. The non-transparent cover 426, which can be composed, for example, of the same material as the spacer 424, extends substantially parallel to the transparent cover 422. Thus, the non-transparent cover 426 and the transparent cover 422 together can form the top of the module, and the spacer 424 can serve as the sidewalls of the module. In some implementations, instead of extending a portion 426 of the spacer 424 over the light emitting element 416, an opaque coating 427, such as black chrome, can be provided on a surface of the transparent cover 422 over the light emitting element 416 (see FIG. 6B). In such implementations, the transparent cover 422 extends over the LED 416 as well as the phosphor material 420, and the opaque coating 427 can be provided either on the light emitting element-side of the cover 422 or on its exterior side. The opaque coating 427, however, does not extend over most or all of the phosphor material 420, thereby allowing the light 430 to exit the module 400A. Further, in some cases, the color of the opaque coating 427 can substantially match a color of the housing of the smartphone or other device 10 in which the module 400A is disposed.

As shown in FIGS. 6C and 6D, some implementations include a reflector 434 at a side of the phosphor material 420 opposite the location of the light emitting element 416 and reflector 432. The surface of the reflector 434 can be coated, for example, with a low-emissivity, highly reflective coating to enhance its reflectivity. The same low-emissivity materials described above can be used for the coating here as well. In some cases, the reflector 434 can be inclined at an angle with respect to the substrate 418. As shown in FIG. 6D, whereas the reflective surface of the reflector 432 faces the substrate 418, the reflective surface of the reflector 434 faces the transparent cover 422. Such arrangements can help increase the amount of light reflected out of the module.

Electrical contacts for the light emitting element 416 can be connected electrically to outside the module 400 (e.g., the exterior of the substrate 418), where conductive pads are attached. The light emitting module 400 thus can be mounted on a printed circuit board, e.g., using surface mount technology (SMT), next to other electronic components. The printed circuit board may be a constituent of the smartphone or other device 10.

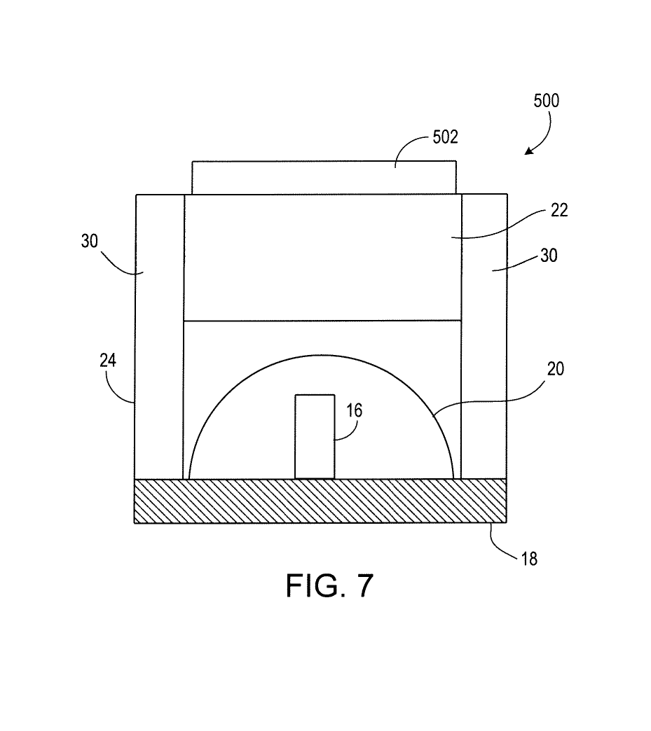

FIG. 7 illustrates another example of a light emitting module 500 that has some features similar to the module 12A of FIG. 2A. Instead of the thin layer 26 with small through-holes 28, the module 500 includes a layer 502 on the transparent cover 22. The layer 502 has a substantially transparent state and a substantially opaque state. In the opaque state, the color of the layer 502 preferably matches the color of the housing of the smartphone or other device 10. In various implementations, the layer 502 can be composed of a material such that the change in state occurs in response to a change in light (e.g., photochromic), a change in temperature (e.g., thermochromic), or a change in voltage or current (e.g., electrochromic). For example, if the layer 502 is photochromic, a change from the opaque state to the transparent state can be triggered in response to the light from the flash LED 16. In particular, when the LED 16 emits light, the photochromic layer 502 would become transparent and light would be emitted from the module 700. A camera in the smartphone or other device 10 may capture an image while the flash in on. The photochromic layer 502 could remain in the transparent state while the LED 16 emits light, and then would transition back to the opaque state after the LED is turned off. If the layer 502 is electrochromic, then additional wiring and contacts can be provided so that the appropriate change in voltage or current can be applied to the electrochromic layer. In some implementations, the layer 502 can be implemented by micro-blind-technology-type materials. Depending on the implementation, the change in state of the layer 502 may be either physical or chemical, or a combination of both.

In some implementations, a neutral density filter can be provided, for example, in the form of a coating on the inner or outer surface of the transparent cover. For example, a neutral density filter can be provided on a surface of the transparent cover 22 in any of the modules of FIG. 4A, 4B or 7. Likewise, a neutral density filter can be provided on a surface of transparent cover 322 in any of the modules of FIG. 5A or 5B, or on a surface of the transparent cover 422 of any of the modules of FIGS. 6A through 6D. The neutral density filter can be used to reduce or modify the intensity of all wavelengths or colors of light by substantially the same amount.

In the foregoing examples, the light source or light emitting element is described as being implemented by a LED. However, in some implementations, the light emitting element can be implemented by other types of light sources, such as a photodiode, an OLED or a laser chip.

The various modules described here can be integrated into a wide range of applications, including consumer electronic devices such as cameras, smart phones and laptops. The modules, particularly, the modules 300, 300A of FIGS. 5A and 5B, also can be suitable for incorporation into vehicle headlamps.

Although particular implementations are described in detail, various modifications can be made within the spirit of the invention. Accordingly, other implementations are within the scope of the claims.

1-26. (canceled)

27. A light emitting module comprising:
a light emitting element mounted on a substrate;
a wavelength conversion material disposed in an area of the module spaced apart from the light emitting element; and
a cover substantially parallel to the substrate and having a first section disposed over the wavelength conversion material and composed of a material that is substantially transparent to light to be emitted from the module,
a substantially opaque layer extending over the light emitting element so as to reduce a visual impact of the light emitting element from outside the module while the light emitting element is not emitting light,
wherein a height of the wavelength conversion material in a direction from the substrate toward the cover is sufficiently small so as to reduce a visual impact of the phosphor when viewed from outside the module while the light emitting element is not emitting light; and
wherein the module is arranged so that at least some light emitted by the light emitting element that enters the wavelength conversion material is converted to light of a different wavelength which subsequently exits the module through the first section of the cover.

28. The light emitting module of claim 27 wherein a ratio of a width to height consumed by the wavelength conversion material is in a range of 5/1 to 100/1.

29. The light emitting module of claim 28 wherein a ratio of a width to height consumed by the wavelength conversion material is in a range of about 10/1 to 50/1.

30. The light emitting module of claim 27 wherein the wavelength conversion material converts the light emitted by the light emitting element to white light.

31. The light emitting module of claim 27 further including a reflector to reflect light emitted by the light emitting element toward the wavelength conversion material.

32. The light emitting module of claim 31 wherein the reflector intersects an optical emission axis of the light emitting element.

33. The light emitting module of claim 31 wherein the reflector comprises a low-emissivity, highly reflective coating.

34. The light emitting module of claim 27 further including a first reflective surface on the same side of the wavelength conversion material as the light emitting element and a second reflective surface on an opposite side of the wavelength conversion material.

35. The light emitting module of claim 27 wherein the substantially opaque layer is composed of the same material as the spacer.

36. The light emitting module of claim 27 wherein the substantially opaque layer comprises a coating on a surface of the cover.

37-41. (canceled)
